(19) United States
(12) Patent Application Publication
(10) Pub. No.: US 2012/0111606 A1
(43) Pub. Date: May 10, 2012

(54) ELECTRONIC CIRCUIT COMPRISING A TRANSFER FACE ON WHICH CONTACT PADS ARE LAID OUT

(75) Inventor: Jean-Pierre Mauclerc, Montrouge (FR)

(73) Assignee: SIERRA WIRELESS, Issy-Les-Moulineaux Cedex (FR)

(21) Appl. No.: 13/293,286

(22) Filed: Nov. 10, 2011

(30) Foreign Application Priority Data
Nov. 10, 2010 (FR) 1059310

(51) Int. Cl. H05K 1/00

(52) U.S. Cl. 174/250

(57) ABSTRACT

An electronic circuit includes a transfer face and a plurality of contact pads. The pads include a first set of pads of a first type in a central zone at the center of the transfer face; second sets of pads of the first type on an end portion of a diagonal of the transfer face; third sets of pads of a second type on a median portion of a diagonal of the transfer face; fourth sets of pads of a third type in a lateral zone demarcated by the central zone and two semi-diagonals joined by one side of the transfer face. Each pad of the first type has a greater surface area on the transfer face than each pad of the second type, and each pad of the second type has a greater surface area than each pad of the third type.

### CROSS-REFERENCE TO RELATED APPLICATIONS

None.

### STATEMENT REGARDING FEDERALLY SPONSORED RESEARCH OR DEVELOPMENT

None.

### THE NAMES OF PARTIES TO A JOINT RESEARCH AGREEMENT

None.

### FIELD OF THE DISCLOSURE

The field of the disclosure is that of the designing and manufacture of electronic circuits (or electronic boards) with which radiocommunications apparatuses for example can be equipped.

More specifically, the disclosure relates to the optimizing of a layout of contact pads on a transfer face of an electronic circuit such as a radiocommunications module for example.

BACKGROUND OF THE DISCLOSURE We shall strive more particularly in the rest of this document to describe the problems and issues existing in the field of radiocommunications that the inventors of the present application have faced. The invention of course is not limited to this particular field of application but is of interest in any technique for laying out contact pads in an electronic circuit that has to cope with a proximate or similar set of problems and issues.

By way of an illustration only, the drawbacks of the prior-art are presented here below in the case of an electronic radiocommunications module of the WISMO (registered mark) family from the company Sierra Wireless (the party filing the present patent application). The company Sierra Wireless has indeed, for many years now, proposed an approach to mitigate a certain number of drawbacks by combining all or at least most of the functions of a radiocommunications device in a single module (commonly called a radiocommunications module). A module of this kind takes the form of a single package, preferably sheathed, which the manufacturers of electronic devices can directly implant without having to take a multitude of components into account. This module (sometimes called a macro-component) is indeed formed by a grouping of several components on a substrate so that it can be implanted in the form of a single element. It comprises a set of electronic components (in particular a processor and memories) implanted in a printed circuit, and software programs needed for the working of a radiocommunications device using the radioelectrical frequencies band. There are therefore no longer any complex steps of conception and validation of design. It is enough to reserve the place needed for the module. Such a module therefore makes it possible to easily, swiftly and optimally integrate all the components in wireless terminals (cellphones, modems, or any other device using a wireless standard).

One of the main preoccupations of builders in the field of radiocommunications is that of designing and manufacturing radiocommunications modules (or more generally electronic circuits) that have numerous functions and are compact, low-cost and mechanically robust.

In practice, a radiocommunications module generally has a set of components implanted on one face while, on the other face (commonly called a transfer face, a printed circuit face or again a printed circuit board (PCB)), it has a zone of contact pads fulfilling functions of electrical interconnection and of transfer to an electronic board, such as a motherboard for example. In addition, for setting up a mechanical or electrical connection between the electronic circuit and the electronic board, the contact pads have the advantage of improving the mechanical strength of the radiocommunications module.

It must be noted that, here below in the document, the term “transfer face” refers to the face of the radiocommunications module (or electronic circuit) designed to be transferred to an electronic board.

A transfer face of this kind, as illustrated in FIG. 1, is formed by a classic layout of BGA (ball grid array) type of contact pads, described in greater detail here below. To put it briefly, this face comprises contact pads of a first type 11, for example dedicated to the ground connection and/or to the feeding of an antenna, and contact pads of a second type 12, for example dedicated to the inputs/outputs of the electronic components and/or to the voltage supply. The contact pads of the second type 12 have a diameter smaller than that of the contact pads of the first type 11.

This classic layout of contact pads however occupies a certain surface area on the transfer face which it is difficult to reduce so as to thus limit the size of the radiocommunications module.

One solution to the problem of space requirement could consist in reducing the size of the set of contact pads laid out on the transfer face of the radiocommunications module.

However, this approach has a certain number of drawbacks. Indeed, the researchers have noted that reducing the size of the contact pads in the same ratio as the size of the radiocommunications module irremediably leads to a deterioration in the robustness of the module. A reduction of mechanical strength of the radiocommunications module would make it fragile or brittle and unsuited to certain uses, as is the case for example when assembling the module on or transferring it to a motherboard.

Furthermore, reducing the size of the contact pads does not make it possible to significantly increase the number of contact pads per unit of surface area or even increase the number at all, thus restricting the number of electronic interconnections that can be implanted on the radiocommunications module.

### SUMMARY

One particular embodiment proposes an electronic circuit comprising a rectangular transfer face on which a plurality of contact pads is laid out, the plurality of contact pads comprising at least:

one first set of pads of a first type, comprising pads placed in a central zone situated at the center of the transfer face;

second sets of pads of the first type, each comprising at least one pad placed on an end portion of one of the diagonals of the transfer face;

third sets of pads of a second type, each comprising at least one pad placed on a median portion of one of the diagonals of the transfer face, each diagonal median portion being situated between the central zone and one of the diagonal end portions;

fourth sets of pads of a third type, each comprising pads placed in a lateral zone demarcated by the central zone and two semi-diagonals joined by one side of the transfer face;

the surface area occupied on the transfer face by a pad of the first type being greater than the surface area occupied on the transfer face by a pad of the second type, and the surface area occupied on the transfer face by a pad of the second type being greater than the surface area occupied on the transfer face by a pad of the third type.

The general principle of this embodiment therefore consists in making, on a transfer face of an electronic circuit, a layout by zones of first, second and third type contact pads that favors a grouping, at the center and in the diagonals of the transfer face, of the contact pads of the first and second types (i.e. pads for which the surface area occupied by the transfer face is the highest).

Thus, unlike in the prior art described here above, the layout of the contact pads implemented in this embodiment reduces the space requirement of the electronic circuit, while at the same time increasing the density of surface pads situated on the transfer face of the electronic circuit.

Furthermore, favoring a grouping of pads of the first and second type (i.e. the contact pads for which the surface area occupied on the transfer face is greater than that occupied by the pads of the third type) at the center and in the diagonals of the electronic circuit improves the robustness of the electronic circuit, thus making it less fragile under the mechanical stresses that the electronic circuit could be subjected to. Indeed, the first, second and third sets of contact pads usually correspond to zones of the transfer face that are frequently subjected to high mechanical stresses.

Advantageously, for each type of contact pad among the first, second and third types, there is a distance between pads that is constant whatever the pair of adjacent contact pads of a same row or of two adjacent rows.

An inter-pad distance of this kind therefore facilitates the routing of the data at the level of the interconnections of the electronic circuit and increases the surface area occupied on the transfer face by the contact pads.

Advantageously, the ratio between the diameter of a pad of the first type and the length of the transfer face ranges from 0.04 to 0.13, the ratio between the diameter of a pad of the second type and the length of the transfer face ranges from 0.027 to 0.09 and the ratio between the diameter of a pad of the third type and the length of the transfer face ranges from 0.018 to 0.06.

Thus, the ratio between the diameter of a contact pad and the length of the module, and therefore also the total number of pads that can be placed on the transfer face is optimized.

According to an advantageous characteristic, the transfer face is square and the first set of pads of the first type placed in the central zone forms a pattern that is not invariable if the transfer face undergoes a 90° rotation about its center.

A pad pattern of this kind makes it possible to carry out an error-prevention or foolproofing test to prevent incorrect assembly or transfer of the electronic circuit on or to an electronic board.

If another foolproofing test has already been implemented (for example by means of a beveled corner of the electronic circuit), the presence of such a pattern provides an additional foolproofing test.

Advantageously, the first set comprises seven pads of the first type, each second set comprises two pads of the first type, each third set comprises four pads of the second type and each fourth set comprises forty-one pads of the third type distributed among six rows.

According to one alternative embodiment, the first set comprises seven pads of the first type, each second set comprises three pads of the first type, each third set comprises four pads of the second type, each fourth set comprises fifty-four pads of the third type distributed over seven rows.

Advantageously, the plurality of contact pads additionally comprises fifth sets of pads of a fourth type each comprising at least one pad placed in a median portion of one of the diagonals of the transfer face, and the surface area occupied on the transfer face by a pad of the fourth type is greater than the surface area occupied on the transfer face by a pad of the second type and smaller than the surface area occupied on the transfer face by a pad of the first type.

The transfer face therefore has a greater diversity of contact pads in its diagonals in terms of surface area.

Advantageously, the plurality of contact pads additionally comprises sixth sets of pads of a fifth type, each comprising at least one pad placed in a lateral zone, and the surface area occupied on the transfer face by a pad of the fifth type is smaller than the surface area occupied on the transfer face by a pad of the third type. The transfer face thus has a greater diversity of contact pads in terms of surface area.

Advantageously, the electronic circuit is a radiocommunications module.

### BRIEF DESCRIPTION OF THE DRAWINGS

Other features and advantages shall appear from the following description, given by way of a non-exhaustive indication and from the appended drawings, of which:

FIG. 1, already described with reference to the prior art, presents a bottom view of a radiocommunications module showing a transfer face on which a known layout of contact pads is implanted;

FIG. 2 illustrates a view of a transfer face of a radiocommunications module according to a first particular embodiment of the disclosure;

FIG. 3 illustrates a view of a transfer face of a radiocommunications module according to a second particular embodiment of the disclosure;

Each of FIGS. 4a and 4b represents a schematic example of computation of density of contact pads for the known layout of pads illustrated in FIG. 1 (FIG. 4a illustrating the case of a central zone and FIG. 4b illustrating the case of a diagonal);

Each of FIGS. 5a and 5b represents a schematic example of computation of density of contact pads for the layout of the pads illustrated in FIG. 2 (FIG. 5a illustrating the case of a central zone and FIG. 5b the case of a diagonal);

FIG. 6 illustrates a magnified view of a part of a transfer face of a radiocommunications module according to a third particular embodiment of the disclosure.

### DETAILED DESCRIPTION OF ILLUSTRATIVE EMBODIMENTS

In all the figures of the present document, the identical elements and steps are designated by a same numerical reference.

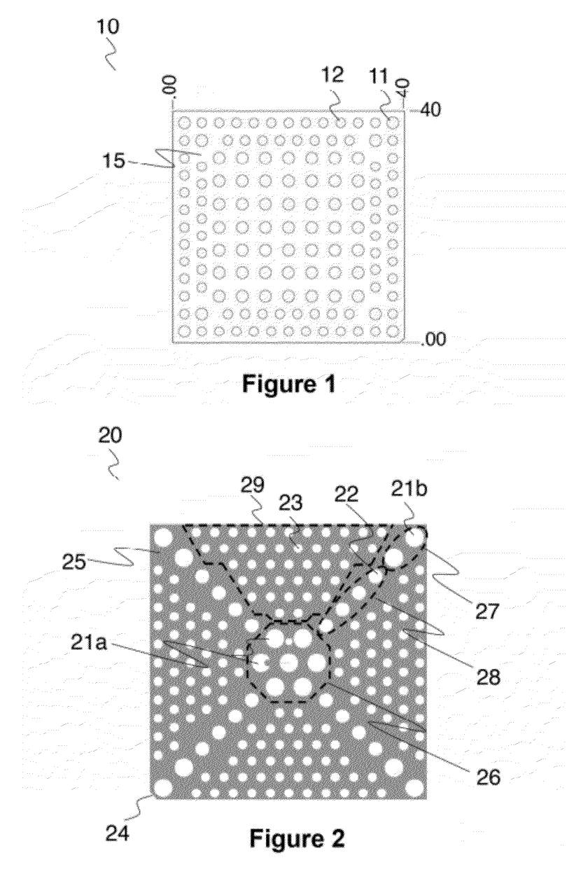

FIG. 1, already described with reference to the prior art, presents a bottom view of a radiocommunications module 10 showing a transfer face 15 on which a layout of contact pads, known in the prior art, is implanted.

The radiocommunications module is shaped as a square, 40 mm×40 mm, and comprises a transfer face 15 itself comprising:

a set of fifty-seven contact pads of a first type (referenced 11 in the figure) with a diameter equal to 2 mm, distributed on the one hand, in the form of a central matrix that is regular at the center, and, on the other hand, in the end zones of the diagonals of the transfer face;

a set of seventy-six contact pads of a second type (12), with a diameter equal to 1.6 mm, distributed among two rows of pads in the form of a ring situated around the regular central matrix of the pads 11 of the first type. The set of contact pads 11 of the first type has a 4 mm horizontal and vertical distance between centers (or spacing). The set of contact pads 12 of the second type has a 3 mm distance between centers of adjacent pads of the same row and a 1.5 mm distance between centers of adjacent pads of two adjacent rows.

The contact pads 11 of the first type are dedicated for example to the ground connection and/or the feeding an antenna, and the pads of a second type 12 are dedicated to the inputs/outputs of the electronic components and/or to the voltage supply.

Here below in the present document, the density of contact pads is defined as being the ratio (denoted as “R”) between the surface area occupied by a set of given pads (denoted as “S_{c}”) on a reference surface area of the transfer face (denoted as “Sᵣ”) and said reference surface area.

Thus, it is noted that the ratio between the surface area occupied by the contact pads and the reference surface area of the transfer face is 11% for the diagonals, 20% for the central pattern and 20% on the entire transfer face. The detail of the computations of density of pads is described further below with reference to FIGS. 4a and 4b.

FIG. 2 illustrates a view of a transfer face 25 of a radiocommunications module 20 according to a first particular embodiment of the disclosure.

The transfer face 25 is rectangular and has a plurality of contact pads laid out as follows:

a first set of seven pads 21a of a first type, comprising pads placed in a central zone 26 situated at the center of the transfer face (for example dedicated to the ground connection and/or to the feeding of an antenna);

four sets of pads 21b of the first type each comprising two pads 21b placed in an end zone 27 corresponding to an end portion of the diagonals of the transfer face;

four sets of pads 22 of a second type (for example dedicated to the ground connection and/or the feeding of an antenna), each comprising four pads 22 placed in a median zone 28 corresponding to a median portion of the diagonals of the transfer face, each median portion of a diagonal being situated between the central zone and one of the end portions of a diagonal;

four sets of pads 23 of a third type (for example dedicated to the inputs/outputs of the electronic components and/or to the voltage supply), each comprising forty-one pads 23 laid out over six rows and placed in a lateral zone 29 demarcated by the central zone 26 and two half-diagonals connected by one side of the transfer face.

The diameters of the pads of first 21, second 22 and third 23 types are respectively 1.80 mm, 1.35 mm and 0.90 mm.

The transfer face of the radiocommunications module 20 is square, 27 mm×27 mm. This represents 45% of the surface area of the prior art transfer face 15 described further above (and illustrated in FIG. 1).

The transfer face 25 therefore has a layout of contact pads in the form of zones 26, 27, 28 and 29 favoring a grouping of the transfer face, the contact pads 21a, 21b and 22 of the first and second types at the center (zone 26) and in the diagonals (zones 27 and 28).

Thus, by increasing the density of contact pads of the first and second types (i.e. the pads of two greater diameters) in the zones of the transfer face sensitive to mechanical stresses, i.e. the center and in the diagonals of the transfer face, the robustness of the radiocommunications module is improved, making it less fragile under mechanical stresses. The contact pads of the third type (i.e. the pads of the smallest diameter) are placed outside the zones sensitive to mechanical stresses, i.e. in the lateral zones 29 situated between the central zone 26 and two half-diagonals connected by a side of the transfer face.

This advantageous layout of pads on the transfer face 35 enables fifteen large-diameter contact pads 21a, 21b, 22 (of the first and second type) to be placed on each diagonal of the transfer face, as against eleven large-diameter contact pads 11 on each diagonal of the prior art transfer face 15 described here above (with reference to FIG. 1).

The ratio between the surface area occupied by the contact pads 21a, 21b of the first type and the pads 22 of the second type on the transfer face 25 illustrated in FIG. 2 and the reference surface area of the transfer face is 33% for the diagonals of the transfer face 25 (against 11% for the prior art transfer face 15 illustrated in FIG. 1), giving an increase of approximately 200%. The ratio between the surface area occupied by the pads 21a, 21b of the first type on the transfer face 25 illustrated in FIG. 2 and the reference surface area of the transfer face is 35% for the central pattern (against 20% for the prior art transfer face 15 illustrated in FIG. 1), giving an increase of 75%. The ratio between the surface area occupied by the contact pads of the first, second and third types (i.e. all the types of pads without distinction) on the transfer face 25 illustrated in FIG. 2 and the reference surface area of the transfer face is 22% for the entire transfer face (against 20% for the prior art transfer face 15 illustrated in FIG. 1), giving an increase of 10%. The detail of the computations of density of pads is given further below with reference to FIGS. 5a and 5b.

Thus, the layout of the contact pads implemented in this embodiment reduces the space requirement of the radiocommunications module 20, while increasing the density of surface pads situated on the transfer face of the module.

Furthermore, the ratio between the diameter of a contact pad and the length of the module is improved for each type of contact. Indeed, the ratio obtained for the diameter of a pad of the first type, the second type and the third type illustrated in FIG. 2 and the length of the transfer face 25 is respectively equal to 0.06 (i.e., 1.80/27) (as against 0.05 for the transfer face 15 of the prior art illustrated in FIG. 1), 0.05 (i.e., 1.35/27) and 0.03 (i.e., 0.90/27). In particular, the ratio for the contact pads of the first type obtained according to the particular layout of contact pads according to a particular embodiment of the disclosure is improved by 20% as compared with the prior art layout illustrated in FIG. 1.

In an example, the ratio between the diameter of a pad of the first type and the length of the transfer face ranges from 0.04 to 0.13, the ratio between the diameter of a pad of the second type and the length of the transfer face ranges from 0.027 to 0.09 and the ratio between the diameter of a pad of the third type and the length of the transfer face ranges from 0.018 to 0.06.

The radiocommunications module 20 furthermore comprises a beveled corner 24 serving as a mechanical error-preventing or foolproofing test aimed at preventing an error from occurring during the assembly or transfer of the radiocommunications module 20 on or to an electronic board.

According to one particular embodiment, the transfer face 25 of the module advantageously has a central foolproofing pattern (corresponding to the central pad zone) formed by contact pads 21a of the first type placed in the central zone. This pattern is invariant when the radiocommunications module incorrectly goes through a 90° rotation about its center. The pattern can be used especially to perform a control additional to the foolproofing test frequently used during the assembling of the radiocommunications module on a motherboard for example.

It must be noted that this error-preventing or foolproofing concept could furthermore be used on a transfer face of a radiocommunications module comprising a classic layout of contact pads such as that of FIG. 1 for example.

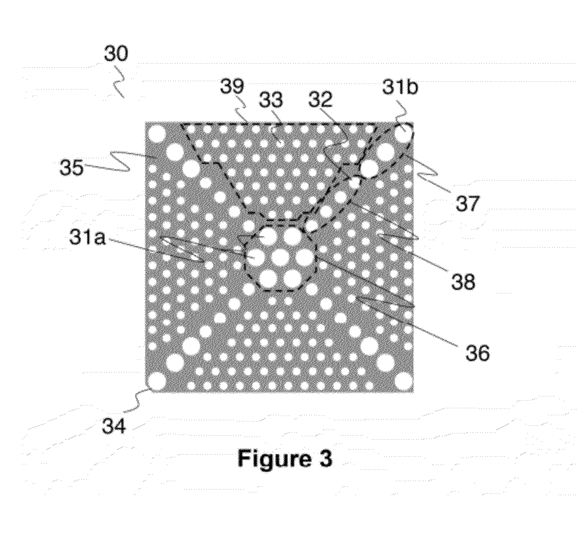

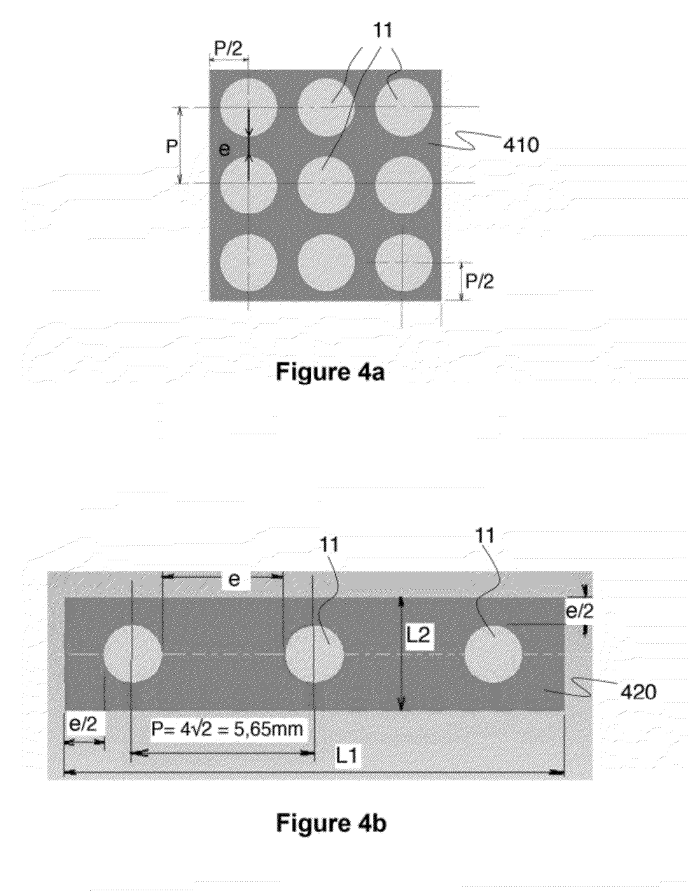

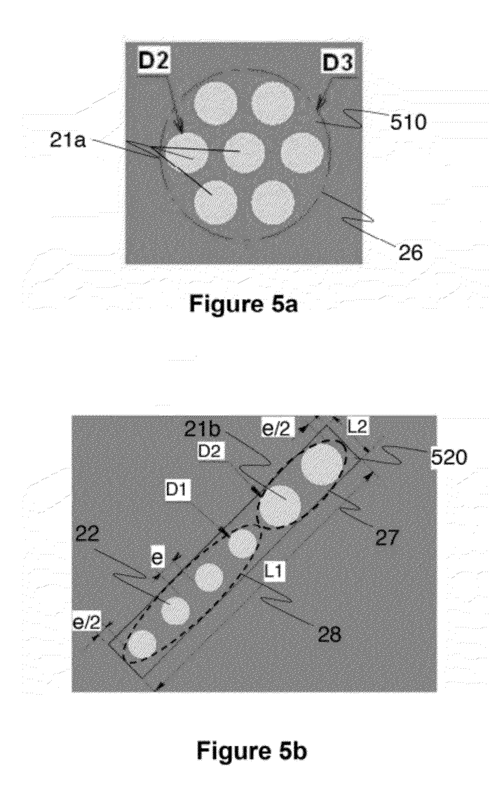

FIG. 3 illustrates a view of a transfer face 35 of a radiocommunications module 30 according to a second particular embodiment of the disclosure.

The transfer face 35 is rectangular and comprises a plurality of contact pads laid out as follows:

a first set of seven pads 31a of a first type, comprising pads placed in a central zone 36 situated at the center of the transfer face (for example dedicated to the ground connection and/or feeding of an antenna); four sets of pads 31b of the first type each comprising three pads 31 placed in an end zone 37 corresponding to an end portion of the diagonals of the transfer face;

four sets of pads 32 of a second type (for example dedicated to the ground connection and/or the feeding of an antenna) each comprising four pads 32 placed in a median zone 38 corresponding to a median portion of the diagonals of the transfer face, each median portion being situated between the central zone and one of the end diagonal portions;

four sets of pads 33 of a third type (for example dedicated to the inputs/outputs of the electronic components and/or to the voltage supply), each comprising fifty-four pads 23 positioned on seven rows and placed in a lateral zone 39 demarcated by the central zone 36 and two half-diagonals connected by one side of the transfer face. The diameters of the pads of the first 31, second 32 and third 33 types are respectively 2.00 mm, 1.35 mm and 0.90 mm. The transfer face 35 of the radiocommunications module 30 is square-shaped, 30 mm×30 mm. This represents 29% of the surface area of the prior art transfer face 15 discussed further above (and illustrated in FIG. 1).

As compared with the layout of pads of the first embodiment (presented further above with reference to FIG. 2), the layout of contact pads illustrated in this figure makes it possible to increase the number of pads 33 of a third type (212 contact pads in FIG. 3 as against 164 contact pads in FIG. 2) placed in the lateral zones 39 of the transfer face 35 (with the addition of an additional row of pads and a greater number of pads per row). This layout furthermore makes it possible to obtain a higher number of contact pads 31a, 3 lb of the first type on the diagonals of the transfer face 35 (19 contact pads in FIG. 3 as against 15 contact pads in FIG. 2) further reinforcing the robustness of the radiocommunications module 30 in the face of mechanical stresses.

Furthermore, the ratio between the surface area occupied by the contact pads of the first, second and third types (i.e. all types of pads without distinction) on the transfer face 35 illustrated in FIG. 3 and the reference surface area of the transfer face is 23% for the entire transfer face (as against 20% for the prior art transfer face 15 illustrated in FIG. 1), giving a 15% increase.

The radiocommunications module 30 furthermore comprises a beveled corner 34 serving as a mechanical foolproofing or error-prevention test aimed at preventing an error during the assembly or transfer of the radiocommunications module 30 on or to an electronic board. According to one particular embodiment, the transfer face 35 of the module also includes a central foolproofing pattern (corresponding to the central pad zone) formed by the contact pads 31a of the first type placed in the central zone, the principle of which is identical to the one developed further above with reference to FIG. 2.

FIGS. 4a and 4b each represent a schematic example of computation of density of contact pads for the prior-art layout of pads illustrated in FIG. 1, FIG. 4a illustrating the computation of density of pads in the case of a central zone and FIG. 4b the computation of density of pads in the case of a diagonal. The central zone chosen for the computation of density (FIG. 4a) comprises a set of nine pads of the first type 11 belonging to the prior-art layout of FIG. 1, each pad of the first type 11 having a diameter Ø of 2 mm. The surface area S_{c} occupied by a pad of the first type 11 is therefore equal to 3.14 mm² (Π×(Ø/2)²), giving a surface area occupied by the set of nine pads equal to 28.26 mm². The reference surface area of the transfer face (Sᵣ) for this central zone is computed on the basis of a square (referenced 410 in the figure) of 12 mm side, including all nine contact pads. Indeed, the reference surface area is defined so that a outline is spaced out from each pad situated on the periphery of the central zone by a distance e/2, e being the space between two adjacent pads (pads not included). The distance e is determined from the pitch P (which corresponds to the distance between two adjacent pads (pads included)) which is equal to 4 mm, according to the following expression: e=P−Ø=2 mm. We thus obtain a square of 12 mm side, and hence a reference surface area Sᵣ=12×12=84.46 mm².

The ratio R between the surface area occupied by the pads 11 and the reference surface area is therefore approximately equal to 20% (R=S_{c}/Sᵣ=28.26/144=0.196) for the central zone.

The diagonal chosen for the computation of density (FIG. 4b) comprises a set of three pads of a first type 11 of the prior-art layout illustrated in FIG. 1. The surface area occupied by the set of three pads is therefore equal to 9.42 mm². The reference surface area of the transfer face (Sᵣ) is computed on the basis of a rectangle (referenced 420 in the figure) defined so that the outline of this rectangle is spaced out from each pad 11 of the diagonal by a distance e/2 with e being the space between two adjacent pads (pads not included). The distance e is determined from the pitch P which is equal to 4√2, giving 5.65 mm according to the following expression: e=P−Ø=3.65 mm. We thus obtain a rectangle length L1=(5.65×2)+6.65=14.95 mm and a rectangle width L2=2+3.65=5.65, and hence a reference surface area Sᵣ=L1×L2=14.95×5.65=84.46 mm².

The ratio R between the surface area occupied by the pads 11 and the reference surface area is therefore approximately equal to 11% (R=S_{c}/Sᵣ=9.42/84.46=0.111) for the diagonal.

For the entire transfer face 15 illustrated in FIG. 1, there are fifty-seven pads of the first type 11 with a diameter equal to 2 mm and seventy-six pads of the second type 12 with a diameter equal to 1.6 mm. The surface area occupied by the set of contact pads on the face 15 is therefore equal to S_{c}=(57×3.14)+(76×2.01)=331.74 mm². Since the surface area occupied by the transfer face 15 (which corresponds to the reference surface area) is equal to 600 mm², the ratio R between the surface area occupied by the set of contact pads and the reference surface area is approximately equal to 20% (R=S_{c}/Sᵣ=331.74/1600=0.207) for the entire transfer face.

FIGS. 5a and 5b each represent a schematic example of computation of density of contact pads for the layout of pads illustrated in FIG. 2, FIG. 5a illustrating the case of a central zone and FIG. 5b illustrating the case of a diagonal.

The central zone chosen for the computation of density (FIG. 5a) comprises a set of seven pads of the first type 21a of the layout illustrated in FIG. 2, each pad of the first type 21a having a diameter D2 of 1.8 mm. The surface area S_{c} occupied by a pad of the first type 21a is therefore equal to 2.54 mm² (Π×(D/2)²), giving a surface area S_{c} occupied by all seven pads equal to 17.78 mm². The reference surface area (Sᵣ) of the transfer face 25 is computed on the basis of a disk (referenced 510 in the figure) with a diameter D3 defined so that the outline of this disk is spaced out from each pad 21a situated on the periphery of the central zone by a distance e/2, with e being the space between two adjacent pads (pads not included). The distance e is determined from the pitch P (which corresponds to the distance between two adjacent pads (pads included)), which is equal to 3.6 mm according to the following expression: e=P−Ø=1.8 mm. We thus obtain a disk with a diameter D3=(3×0.9)+(3×1.8)=8.1 mm, and therefore a reference surface area Sᵣ=Π×(D3/2)² =51.53 mm². The ratio R between the surface area occupied by the pads 21a and the reference surface area is therefore approximately equal to 35% (R=S_{c}/Sᵣ=17.78/51.53=0.345) for the central zone.

The diagonal chosen for the computation of density (FIG. 5b) comprises a set of two pads of the first type 21b and four pads of the second type 22 of the layout illustrated in FIG. 2. The surface area S, occupied by the set of pads of this diagonal is therefore equal 1.43 mm² S_{c}=(4×1.43) +(2×2.54)=10.8 mm².

The reference surface area Sᵣ of the transfer face 25 is computed on the basis of a rectangle (referenced 520 in the figure) all the pads of the diagonal. Indeed, this rectangle is defined so that its outline is spaced out from each pad 22 by a distance e/2 with e being the space between two adjacent pads of the second type 22 (pads not included), e being equal to 0.9 mm. We thus obtain a rectangle length L1=20.4 mm and a rectangle width L2=D1+e=2.25, and therefore a reference surface area Sᵣ=L1×L2=14.4×2.25=32.4 mm².

The ratio R between the surface area occupied by the pads of the first type 21b and second type 22 and the reference surface area is therefore approximately equal to 33% (R=S_{c}/Sᵣ=10.8/32.4=0.333) for the diagonal.

For the entire transfer face 25 illustrated in FIG. 2, we have fifteen pads of the first type 21a, 21b with a unit surface area equal to 2.54 mm², sixteen pads of the second type 22 with a unit surface area equal to 1.43mm², and one hundred and sixty-four pads of the third type with a unit surface area equal to 0.636mm². The surface area occupied by the set of contact pads on the face 25 is therefore equal to S_{c}=(15×2.54)+(16×1.43)+(164×0.636)=165.31 mm². Since the total surface area of the transfer face 25 (which corresponds to the reference surface area) is equal to 27×27=729 mm², the ratio R between the surface area occupied by the contact pads and the reference surface area is therefore approximately equal to 22% (R=S_{c}/Sᵣ=165.31/729=0.226) for the entire transfer face.

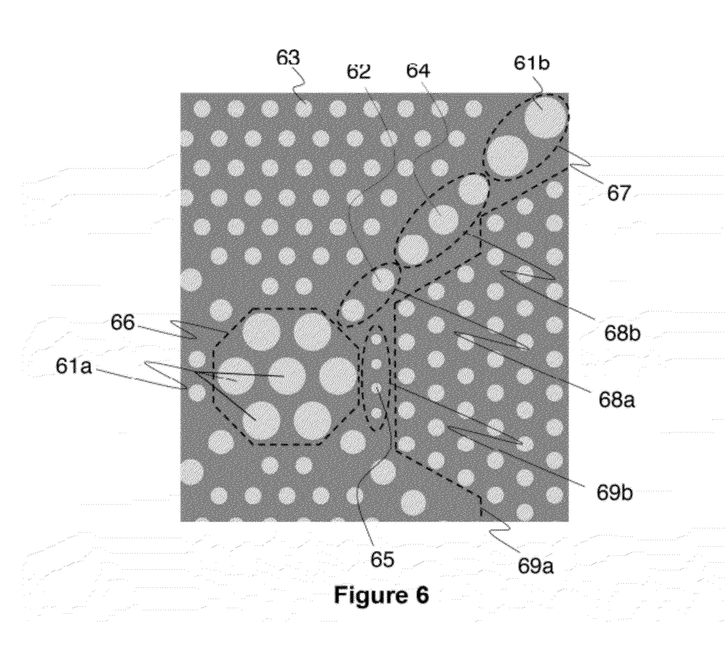

FIG. 6 represents an enlarged view of a part of a transfer face of a radiocommunications module according to a third particular embodiment of the disclosure. In this particular embodiment, the transfer face comprises:

a first set of seven pads 61a of a first type, comprising pads placed in the central zone 66 situated at the center of the transfer face;

a set of two pads 61b of the first type placed in an end zone 67 corresponding to an end portion of the diagonals of the transfer face;

a set of two pads 62 of a second type placed in a first median zone 68a corresponding to a median portion of the diagonals of the transfer face;

a set of three pads 64 of a second type placed in a second median zone 68b corresponding to a median portion of the diagonals of the transfer face situated between the end zone 67 and the first median zone 68a;

a set of fifty-two pads 63 of a third type, positioned on six rows and placed in a first lateral zone 69a demarcated by two semi-diagonals joined by one side of the transfer face;

a set of four pads 65 of a fifth type, positioned on a single row placed in a second lateral zone 69b, this second lateral zone 69b being demarcated by the central zone 66, the first lateral zone 69a and two semi-diagonals joined by one side of the transfer face.

It can be noted that the surface area occupied on the transfer face by a pad 64 of the second type is greater than the surface area occupied on the transfer face by a pad 62 of the second type and is smaller than the surface area occupied by the transfer face on a pad 61a, 61b of the first type. Also, the surface area occupied on the transfer face by a pad 65 of the fifth type is smaller than the surface area occupied on the transfer face by a pad 63 of the third type.

The transfer face therefore has a layout of contact pads in the form of zones 66, 67, 68a and 68b, 69a and 69b favoring a grouping at the center (zone 66) and in the diagonals (67, 68a and 68b) of the transfer face, contact pads 61a, 61b, 62 and 64 for which the surface area occupied on the transfer face is great (as compared with the pads 63, 65 placed in the lateral zones 69a and 69b).

It can be noted for example that all the contact pads illustrated for example in the examples of FIGS. 2 to 6 are of the BGA (ball grid array) type.

The type of contact pads may belong to the following list (non-exhaustive): BGA, CGA, DIM, DIP, DSO, DSB, LGA, PGA, QFF, QFJ, QFN, QFP, SIM, SIP, SOF, SOJ, SON, SVP, UCI, WLB, ZIP.

By way of an illustration, FIGS. 2, 3 and 6 present three particular embodiments of layouts of contact pads on a transfer face of a radio communications module. However, the type of contact pads (i.e. their nature (BGA for example) and their dimension (diameter for example)), as well as their layout on the transfer face can be any other without departing from the framework of the disclosure. Indeed, it is clear that a layout based on a greater number of pads and/or a greater diversity of pads in terms of dimensions would also be suitable for the implementation of one or more embodiments of the disclosure.

At least one embodiment of the disclosure provides a technique that optimizes the layout of the contact pads on a transfer face of an electronic circuit so as to reduce the space requirement of such a circuit.

At least one embodiment of the disclosure provides a technique of this kind that increases the number of contact pads per unit of surface area that are available to an electronic circuit and thus provides a more significant panel of electronic functions.

At least one embodiment of the disclosure provides a technique of this kind that reinforces the mechanical strength of an electronic circuit.

At least one embodiment of the disclosure provides a technique of this kind that is simple to implement and costs little.

Although the present disclosure has been described with reference to one or more examples, workers skilled in the art will recognize that changes may be made in form and detail without departing from the scope of the disclosure and/or the appended claims.

1. An electronic circuit comprising:
a rectangular transfer face; and
a plurality of contact pads laid out on the transfer face, wherein the plurality of contact pads comprises at least:
a first set of pads of a first type, comprising pads placed in a central zone situated at the center of the transfer face;
second sets of pads of the first type, each comprising at least one pad placed on an end portion of one of the diagonals of the transfer face;
third sets of pads of a second type, each comprising at least one pad placed on a median portion of one of the diagonals of the transfer face, each diagonal median portion being situated between the central zone and one of the diagonal end portions;
fourth sets of pads of a third type, each comprising pads placed in a lateral zone demarcated by the central zone and two semi-diagonals joined by one side of the transfer face;
and wherein the surface area occupied on the transfer face by a pad of the first type is greater than the surface area occupied on the transfer face by a pad of the second type, and the surface area occupied on the transfer face by a pad of the second type is greater than the surface area occupied on the transfer face by a pad of the third type.

2. The electronic circuit according to claim 1 wherein, for each type of contact pad among the first, second and third types, there is a distance between pads that is constant whatever the pair of adjacent contact pads of a same row or of two adjacent rows on the transfer face.

3. The electronic circuit according to claim 1, wherein:
the ratio between the diameter of a pad of the first type and the length of the transfer face ranges from 0.04 to 0.13,
the ratio between the diameter of a pad of the second type and the length of the module transfer face ranges from 0.027 to 0.09,
the ratio between the diameter of a pad of the third type and the length of the transfer face ranges from 0.018 to 0.06.

4. The electronic circuit according to claim 1, wherein the transfer face is square-shaped and wherein the first set of pads of the first type placed in the central zone forms a pattern that is not invariable if the transfer face undergoes a 90° rotation about its center.

5. The electronic circuit according to claim 1, wherein:
the first set comprises seven pads of the first type,
each second set comprises two pads of the first type,
each third set comprises four pads of the second type,
each fourth set comprises forty-one pads of the third type distributed among six rows.

6. The electronic circuit according to claim 1, wherein:
the first set comprises seven pads of the first type,
each second set comprises three pads of the first type,
each third set comprises four pads of the second type,
each fourth set comprises fifty-four pads of the third type distributed over seven rows.

7. The electronic circuit according to claim 1, wherein:
the plurality of contact pads further comprises fifth sets of pads of a fourth type each comprising at least one pad placed in a median portion of one of the diagonals of the transfer face, and wherein
the surface area occupied on the transfer face by a pad of the fourth type is greater than the surface area occupied on the transfer face by a pad of the second type and smaller than the surface area occupied on the transfer face by a pad of the first type.

8. The electronic circuit according to claim 1, wherein:
the plurality of contact pads further comprises sixth sets of pads of a fifth type, each comprising at least one pad placed in a lateral zone, and
the surface area occupied on the transfer face by a pad of the fifth type is smaller than the surface area occupied on the transfer face by a pad of the third type.

9. The electronic circuit according to claim 1, wherein said electronic circuit comprises a radiocommunications module.
